(19) United States
(12) Patent Application Publication
(10) Pub. No.: US 2025/0184631 A1
(43) Pub. Date: Jun. 5, 2025

(54) IRIS: INTEGRATED RETINAL FUNCTIONALITY IN IMAGE SENSORS

(71) Applicants: UNIVERSITY OF SOUTHERN CALIFORNIA, Los Angeles, CA (US); NORTHWESTERN UNIVERSITY, Evanston, IL (US)

(72) Inventors: Akhilesh JAISWAL, Madison, WI (US); Gregory SCHWARTZ, Evanston, IL (US); Ajey Poovannummoottil JACOB, Watervliet, NY (US); Zihan YIN, Los Angeles, CA (US); Md ABDULLAH-AL KAISER, Los Angeles, CA (US)

(21) Appl. No.: 19/046,353

(22) Filed: Feb. 5, 2025

Related U.S. Application Data
(63) Continuation of application No. PCT/US2023/071788, filed on Aug. 7, 2023.
(60) Provisional application No. 63/395,725, filed on Aug. 5, 2022.

(51) Int. Cl. H04N 25/47; H04N 23/71; H04N 25/76; H04N 25/79

(52) U.S. Cl. CPC H04N 25/47; H04N 23/71; H04N 25/7795; H04N 25/79

(57) ABSTRACT

Provided are circuits for integrating image processing into image sensors. Multiple configurations of sensors are described that generate specific motion and shape-based responses to changes in received light intensity. These sensor configurations may be used to pre-process images and to provide additional context to light intensity data. The sensor configurations may include memory circuits and signal conditioning.

### CROSS-REFERENCE TO RELATED APPLICATIONS

This application claims the benefit of U.S. Provisional Patent Application 63/395,725, titled IRIS: INTEGRATED RETINAL FUNCTIONALITY IN IMAGE SENSORS, filed 5 Aug. 2022. The entire contents of each afore-mentioned patent filing is hereby incorporated by reference.

### BACKGROUND

### 1. Field

The present disclosure relates generally to image sensors and, more specifically, to pixels with integrated processing capabilities.

### 2. Description of the Related Art

Computer vision often relies on light intensity-based pixel data collected through state-of-the-art CMOS image sensors. However, in almost all cases, appropriate context for the signals transmitted by the pixels is missing (or are extremely vague) with respect to the ‘real-world events’ being captured by the sensor. Thus, the onus of processing is rather put on algorithms, such as intelligent machine learning algorithms, to pre-process, extract appropriate context, and make intelligent decisions based on light intensity-based pixel data. Such a vision pipeline (e.g., processing procedure from pixel to processor) may lead to 1) complex machine learning algorithms designed to cater to image/video data without appropriate context 2) increased the time to decision, associated with the processing time of the machine learning algorithms 3) energy-hungry and slow access to pixel data being captured and generated by the CMOS image sensor. None of which is to suggest that any technique suffering to some degree from these issues is disclaimed or that any other subject matter is disclaimed.

### SUMMARY

The following is a non-exhaustive listing of some aspects of the present techniques. These and other aspects are described in the following disclosure.

Some aspects include sensors with circuitry which may generate specific responses to types of movement and/or shapes of objects.

Some aspects include circuit structures for implementation of retinal-analogous computations, including using advanced 3D integration of semiconductor chips.

Some aspects include a structure and/or method of forming a structure for Active Pixel Sensor (APS) based bipolar spike generator circuitry.

Some aspects include a structure and/or method of forming a structure for transistor-based circuitry for object motion sensitivity.

Some aspects include a structure and/or method of forming a structure for mapping overlapping center-surround receptive field in two-dimensional arrays, including for cameras.

Some aspects include implementation of some computations in inner layers of a camera's image array (e.g., in pixels analogous to retina components).

Some aspects include a structure and/or method of forming a structure capable of extracting object motion and/or shape features, including in faster and/or less energy consuming ways that in CMOS and DVS image sensors.

### BRIEF DESCRIPTION OF THE DRAWINGS

The above-mentioned aspects and other aspects of the present techniques will be better understood when the present application is read in view of the following figures in which like numbers indicate similar or identical elements:

FIGS. 1A-1B are representational views of biological retina and an analogous circuit for an IRIS device implementing retinal computation, respectively, according to one or more embodiments.

FIG. 2A is a representational view of a biological Object Motion Sensitive (OMS) circuit, according to one or more embodiments.

FIG. 2B is a representative view of a biological Looming Detection (LD) circuit, according to one or more embodiments.

FIG. 3A is a representative diagram of a CMOS implementation of the Active Pixel Sensor (APS) Pixel, according to one or more embodiments.

FIG. 3B is a representative diagram of the Dynamic Vision Sensor (DVS) Pixel circuit, according to one or more embodiments.

FIG. 3C is a representative diagram of the timing waveform of the retinal bipolar functionality using APS and DVS Pixels, according to one or more embodiments.

FIG. 4A is a representational diagram of a CMOS implementation of the OMS circuit, according to one or more embodiments.

FIG. 4B is a representational diagram of a waveform of the voltage of Cᵢₙₜ and OUT with varying numbers of ON pixels in the Center Region of the implementation of FIG. 4A, according to one or more embodiments.

FIG. 4C is a representational diagram of a Timing waveform with one Center and one Surround Pixel of the implementation of FIG. 4A, according to one or more embodiments.

FIGS. 5A-5B are representational diagrams of implementation of center-surround receptive field in a 2D array of pixels and biological receptive fields corresponding to neighboring ganglion cells to which the pixel array is analogous, respectively, according to one or more embodiments.

FIG. 6A is a representational diagram of CMOS implementation of Looming Detection Circuit diagram, according to one or more embodiments.

FIG. 6B is a representational diagram of a Timing Waveform of the retinal Looming functionality showing the output voltage in three different scenarios for the implementation of FIG. 6A, according to one or more embodiments.

FIG. 7 is a representational illustration of heterogeneously integrated IRIS system, built on backside illuminated CMOS image sensor (Bi-CIS), according to one or more embodiments.

FIGS. 8A-8C are representational diagrams of CMOS implementation of the OMS circuit with various types of in-circuit memory, according to one or more embodiments.

FIGS. 9A-9B are representational diagrams of CMOS implementation of the OMS circuit with various types of memory integrated into charge integration circuity, according to one or more embodiments.

FIG. 10 is a representational diagram of CMOS implementation of the OMS circuit with signal conditioning, according to one or more embodiments.

FIG. 11 illustrates an example computing system using integrated retinal functionality in image sensors, according to some embodiments.

While the present techniques are susceptible to various modifications and alternative forms, specific embodiments thereof are shown by way of example in the drawings and will herein be described in detail. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims.

### DETAILED DESCRIPTION OF CERTAIN EMBODIMENTS

To mitigate the problems described herein, the inventors had to both invent solutions and, in some cases just as importantly, recognize problems overlooked (or not yet foreseen) by others in the field of image sensing. Indeed, the inventors wish to emphasize the difficulty of recognizing those problems that are nascent and will become much more apparent in the future should trends in industry continue as the inventors expect. Further, because multiple problems are addressed, it should be understood that some embodiments are problem-specific, and not all embodiments address every problem with traditional systems described herein or provide every benefit described herein. That said, improvements that solve various permutations of these problems are described below.

Animal eyes (e.g., eye structure) are extremely diverse and may be specialized for the environment and behavioral niche of each species. Specialization may be particularly robust in the retina, a part of the central nervous system containing parallel circuits for representing or capturing different visual features. In contrast, the engineered ‘eyes,’ e.g., image sensor technology, used in machine vision, may be highly stereotyped. Even though cameras or other imaging devices may have different optics on the front end, the image sensor chip, which may represent the electronic analogue of the biological retina, may essentially be a two-dimensional array of pixels with each transmitting a luminance signal at a fixed frame rate. In some embodiments, the efficiency and performance of machine vision may be improved by using specialized image sensors that replicate some of the feature-selective computations performed in biological retinas.

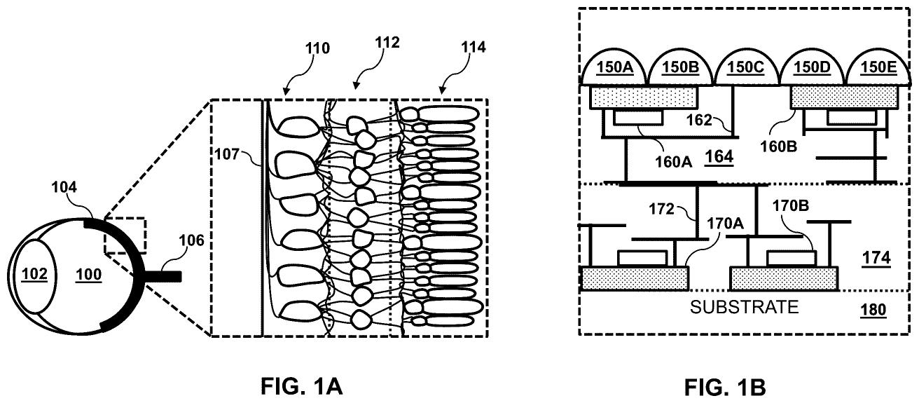

FIG. 1A is a representational view of a biological retina, for which one or more embodiment may function analogously. Rod and cone photoreceptors 114 form an input layer of the vertebrate retina where they transduce light into an analog voltage signal that is then transmitted via bipolar cells 112 to the inner retina 104. Signals may diverge at this first synapse from each cone photoreceptor onto approximately 15 different bipolar cell types. Functional divergence and the sophistication of visual processing then increase dramatically in the inner retina where more than 60 amacrine cell types shape the signals to implement various computations. Finally, signals from bipolar and amacrine cells are collected by over 40 types of retinal ganglion cells (RGCs) 110, the output cells of the retina whose axons form the optic nerve 106. A representational view of key cells type in the retina and their organization is shown in FIG. 1A, which depicts eye 100 with lens 102, the retina 104 and optic nerve 106. The retina contains a retinal surface 107, a layer of RGCs 110, a layer of bipolar cells 112 and amacrine cells, and a layer of rod and cone photoreceptors. RGCs may transmit spike trains (e.g., electrical impulse signals) that carry information about specific visual features like object movement, direction, orientation, and color contrast. Each RGC type may provide a full representation of visual space. Thus, while the input layer of the retina is analogous to an analog pixel array (albeit one with built-in filtering and gain control), once the photoreceptor signals have been processed by the dozens of cell types comprising retinal circuits, the output representation is very different, representing specific visual features. Binary RGC spike trains may convey information about more than 40 different visual features to the brain, and each point in visual space is represented in parallel in all of the feature-selective RGC outputs.

Efforts to bring biologically-inspired functionality to electronic image sensors date back to at least the 1980s with the advent of neuromorphic sensors. Two related aspects of visual computation, which were recognized in retinal neurobiology by the late 1980s, have dominated the field of neuromorphic vision sensors. The first idea was to mimic luminance adaptation, the computation used by the retina to adjust the dynamic range of its biological components to that of the visual scene. Humans may use vision over 10 orders of magnitude of luminance and even single natural images may vary in brightness by more than a factor of 10⁵. These high dynamic ranges may be poorly represented by linear photodiodes and digitization to 8 or even 12 bits. High dynamic range (HDR) cameras use multiple exposures to reconstruct an image, trading bit depth for frame rate, while logarithmic detectors use range compression to avoid saturation. The second aspect of retinal computation to take hold in neuromorphic image sensors is change detection—the propensity of retinal neurons to adapt to the mean luminance over time and only transmit information about its change. Event based cameras, or Dynamic Vision Sensors (DVS), may implement temporal differentiation at each pixel and asynchronously transmit binary ‘spike’ events when the luminance change exceeds a threshold. The asynchronous transmission of DVS cameras has critical advantages for high-speed operation, since it is not limited by frame rate, and for efficiency (e.g., energy efficiency, data transmission efficiency, etc.), since pixels that do not change do not transmit data.

In some embodiments, a new class of neuromorphic sensors referred to herein as Integrated Retinal Functionality in Image Sensors (IRIS) is presented. By leveraging understanding of inner retinal circuits, IRIS technology may go beyond luminance adaptation and change detection—features mostly confined to phototransduction and the first retinal synapse—to implement computations that occur in the circuits of the inner retina (or analog), mimicking the feature-selective spike trains of RGCs. In some embodiments, IRIS circuits implementing either (or both) of two retinal motion computations are presented: Object Motion Sensitivity (OMS) and Looming Detection (LD). In some embodiments, the effect of the present disclosure may not be to implement the detailed electro-chemical dynamics of retinal cell types, but rather to functionally mimic the computational behavior of retinal circuits on image sensing platforms.

In some embodiments, OMS may include a computation that enables the visual system to discriminate motion of objects in the world (object motion) from motion due to one's own eye, head, and body movements (self-motion). A subset of RGCs respond to either local motion in the receptive field ‘center’ or differential motion of the receptive field ‘center’ and ‘surround’ regions but remains silent for global motion. OMS RGCs may be important in detecting movements of predators and prey amidst a background of self-motion. In some embodiments, for example for machine vision applications, a fast sensor with built-in OMS may detect moving objects even if the camera itself was moving, for example, on an autonomous vehicle.

In some embodiments, LD may be include a computation analogous to that which may have evolved to warn animals of approaching threats, especially those from overhead. Loom-sensitive RGCs may respond selectively to expanding (e.g., approaching) dark objects—with much weaker responses to other movement, such as translational motion across the visual field. Experiments in flies, zebrafish, frogs, and mice may have established a causal role for LD RGCs signal transmission in eliciting stereotyped escape responses. In machine vision, an LD-equipped sensor may be used on an autonomous vehicle to avoid collisions by enabling fast detection of approaching objects in large area receptive fields.

In some embodiments, OMS and LD circuits may be built on standard Complementary Metal Oxide Semiconductor (CMOS) pixels as well as on DVS pixels. In some embodiments, advances in semiconductor chip stacking technology and highly-scaled, dense CMOS transistors are exploited, such as to embed retina-inspired circuits in a hierarchical manner analogous to the processing layers of the biological retina (shown in FIG. 1B). FIG. 1B is a representational view of a CMOS for a IRIS device implementing retinal computation, containing micro lenses 150A-150E selecting for color-sensitivity of pixels or sub-pixels, photodiodes 152A-152E, MOS transistors 160A, 160B in a sensor die level 164, MOS transistors 170A, 170B in a processing die level 174, on a substrate 180. Output of the sensor die level 164 and input of the processing die level 174 may be communicated along signal routing lines 162, 172, which may be metal lines. Communication between the sensor die level 164 and the processing die level 174 may include communication through vias, including through-silicon-vias (TSVs). Communication between the sensor die level 164 and the processing die level 174 may be though the use of copper-copper bonding (e.g., Cu—Cu bonding). Micro lenses 150A-150E may be red-green-blue (RGB) micro lenses, or have any other appropriate pixel or sub-pixel color selection scheme. The sensor die level 164 may function to produce signal processing analogous to that of bipolar cells in a biological retina. The processing die level 174 may function to produce signal processing analogous to that of amacrine and ganglion cells in a biological retina. In some embodiments, simulations may demonstrate the prevalence of OMS and LD triggering stimuli in natural scenes from moving vehicles, and may show circuit designs that implement both the OMS and LD computations and may be compatible with existing image sensor fabrication technology. In some embodiments, techniques are used build IRIS-equipped cameras for machine vision.

### Algorithmic Implementation of Retinal Computations

Feature selective circuits in the vertebrate retina, like OMS and LD, may be built from some 5 classes of neurons. Photoreceptors may form the input layer (like the pixels in a camera) and retinal ganglion cells (RGCs) may represent the output. The computations that transform the pixel-like representation of the photoreceptors to the feature selective representation of RGCs may be carried out by the some 3 interneuron classes, including: horizontal cells, bipolar cells, and amacrine cells. Horizontal cells may mainly be involved in lateral inhibition and color processing, but may not play a major role in OMS and LD circuits, which is not to say that circuity performing functions analogous to horizontal cells may not be included in one or more embodiment of the present disclosure. In some embodiments, the components of IRIS circuits may be designed to match the functionality of bipolar and amacrine cells in these computations.

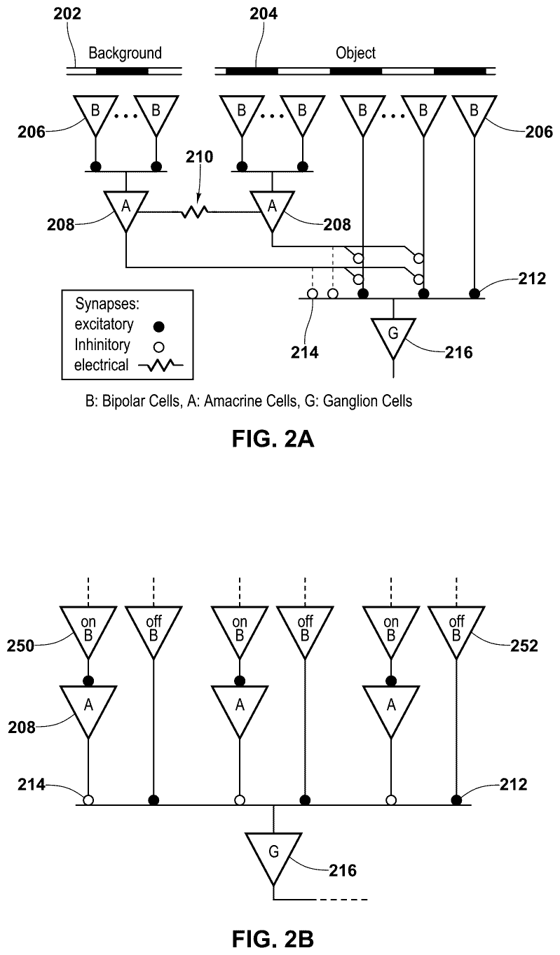

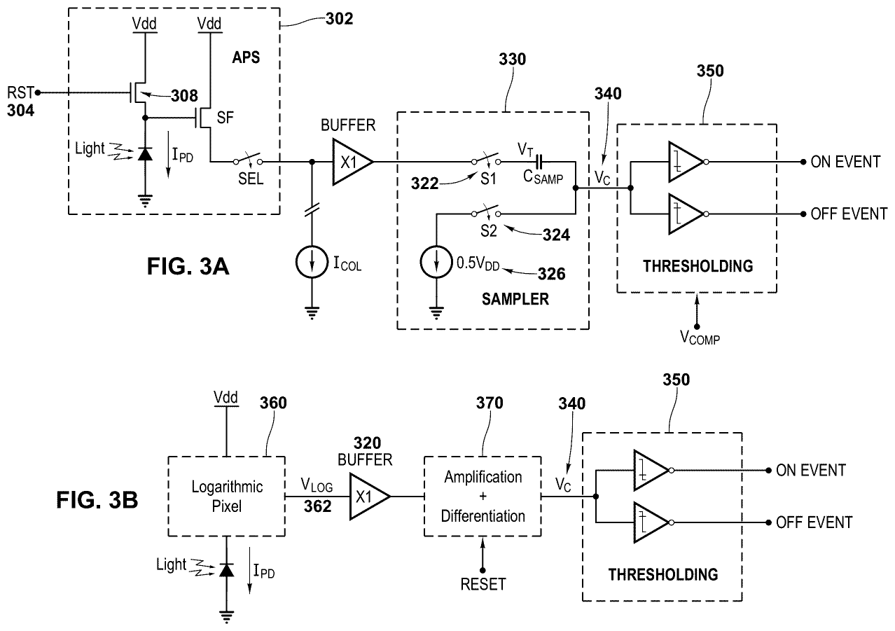

FIG. 2A is a representational view of a biological Object Motion Sensitive (OMS) circuit and FIG. 2B is a representative view of a biological Looming Detection (LD) circuit. In some embodiments, both computations may begin with bipolar cells (or the MOS analog) that may act as differentiators; they may adapt (including rapidly (e.g., on the order of retinal cells)) to steady illumination and signal only changes in luminance. In the biological retina, separate bipolar cells may carry signals for positive (ON) and negative (OFF) changes in illumination. The OMS circuit (shown in FIG. 2A) combines this functionality at the level of ON-OFF bipolar-like units 206, while the LD circuit (shown in FIG. 2B) has separate ON bipolar sub-circuits 250 and OFF bipolar sub-circuits 252.

Amacrine cells may be the most diverse class of neurons in the retina, comprising more than 60 cell types. While some of the cellular and synaptic details of amacrine cells may remain imperfectly understood, their algorithmic role in the OMS and LD circuits may be well characterized. In the OMS circuit of FIG. 2A, amacrine cell analogs 208 may collect the bipolar cell contrast responses (or bipolar-spikes) from the ON-OFF bipolar-like units 206 from a wide spatial extent, the receptive field ‘surround’ or background 202, and relay this summed signal with an opposite sign to that in the receptive field ‘center’ or for object 204, implementing a spatial filter with a subtraction operation. The output of multiple amacrine cell analogs 208 may be combined or compared by an electrical element 210 and may be fed to a RGC analog 216 for further processing (e.g., accumulation, reset, etc.). Connections between various levels (e.g., between ON-OFF bipolar-like units 206, amacrine cell analogs 208 and RGC analogs 216) may be excitatory or inhibitory, as indicated by hollow circles 212 and filled circles 214, respectively. In the LD circuit of FIG. 2B, amacrine cell analogs 208 may also invert the sign of signals from bipolar cell analogs, such as ON bipolar sub-circuits 250 and OFF bipolar sub-circuits 252, but on a smaller spatial scale. OFF signals from the leading edge of a dark moving object may be relayed directly by OFF bipolar cells to RGC analogs 216, while ON signals from the trailing edge of the object may be relayed with opposite sign to the RGC analogs 216 via intermediary amacrine cell analogs 208. Thus, moving objects with both OFF and ON edges may elicit opposing responses that cancel at the level of the RGC, while expanding dark objects that may have only OFF edges, may elicit an RGC response from the RGC analogs 216.

### Embedding OMS Functionality in Image Sensors

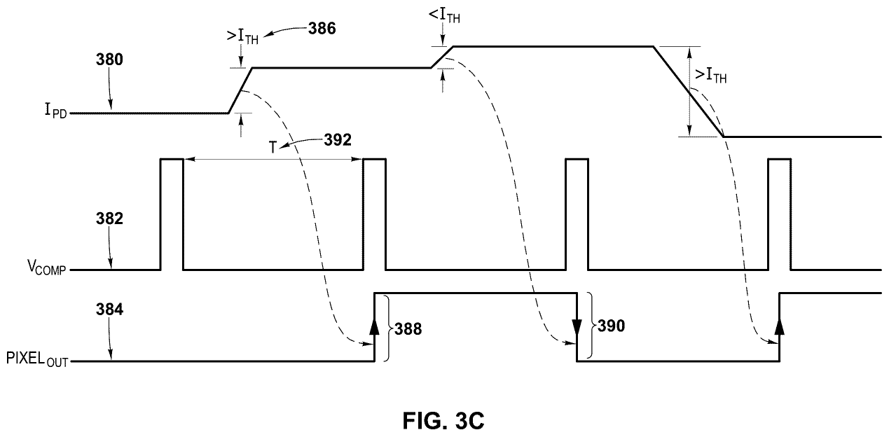

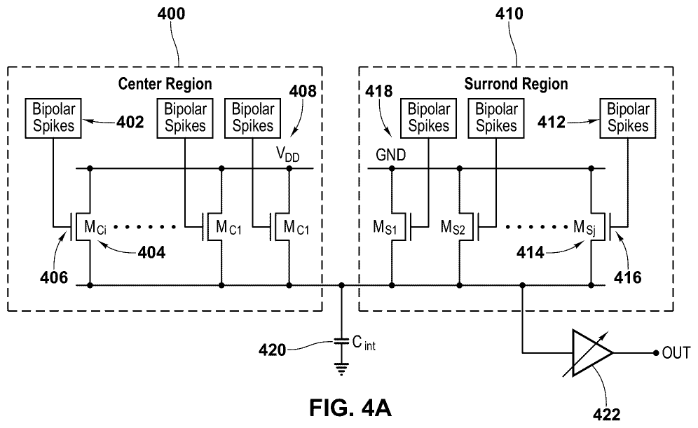

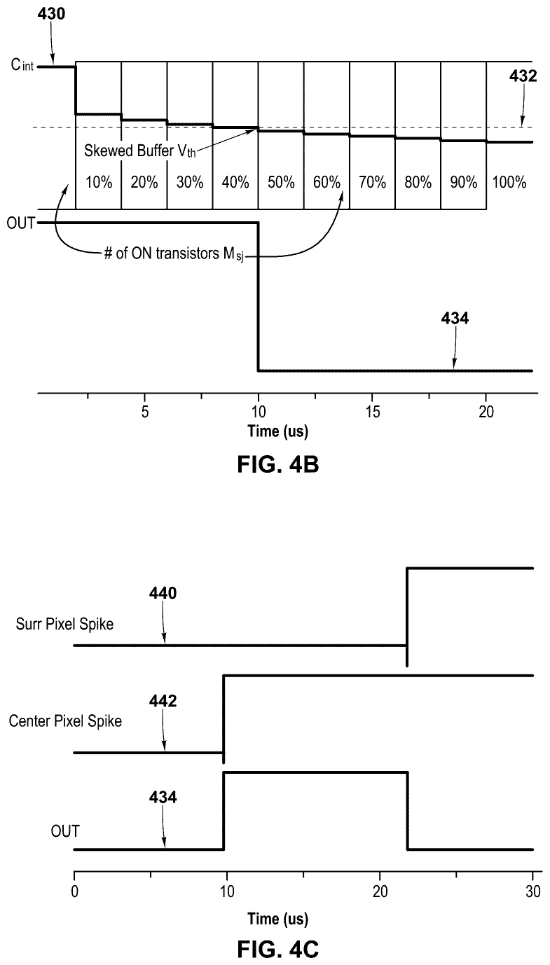

As described above, the OMS computation in the retina may start by detection of change in temporal contrast of input light by the bipolar cells. In other words, for OMS behavior, functionally, the bipolar cells generate a spike for a change in light intensity above a certain threshold. FIGS. 3A-3B show solid-state circuits, according to one or more embodiments, that may mimic the bipolar cell's contrast sensitive behavior using conventional CMOS Active Pixel Sensor (APS) and Dynamic Vision Sensor (DVS), respectively. FIG. 3A is a representative diagram of a CMOS implementation of the Active Pixel Sensor (APS) Pixel and FIG. 3B is a representative diagram of the Dynamic Vision Sensor (DVS) Pixel circuit. In some embodiments, APS pixels may form the backbone of state-of-the-art camera technology and wide class of computer vision applications.

In some embodiments, for APS-based implementation the focal plane array may be formed by a two-dimensional array of APS pixels with additional circuitry to enable light contrast-change detection. In some embodiments, the array of such contrast-change sensitive APS pixels may sample the input light intensity for each frame, such as in parallel, and compare it to the light intensity of the next frame. In some embodiments, if the light intensity sensed by each APS pixel increases (decreases), the contrast sensitive APS pixels may generate an ON (OFF) spike.

In some embodiments, the APS-based contrast-change detection circuit may be implemented such as as-shown in FIG. 3A. For an APS pixel 302, the output voltage of the three transistor (3T) pixel circuit (where the selection component is depicted as a switch SEL which may be a transistor) may be inversely linear proportional to the incident light intensity received at photodiode IPD. The APS pixel may contain transistors 308 and SF and Reference Secondary Tertiary (RST) input line 304 for timing, sampling, synchronization, etc. The RST input line 304 may instead accept any other appropriate reset or timing signal. A source follower buffer (X1) 320 may isolate the sensitive pixel node from the noisy switches (S1 322) and (S2 324) in the SAMPLER block 330. The SAMPLER block 330 may sample the pixel output, in parallel for each frame, and may performs analog subtraction operation between two consecutive samples (or frames) for each pixel, such as simultaneously. The subtraction operation may start by sampling the buffered APS pixel 302 voltage of the first frame, which may be applied on the top-plate, and a constant 0.5V_{DD} 326, which may be applied on the bottom plate, via the sampling capacitor 328 (C_{SAMP} 328). Top and bottom plate terminology is relative and should not be taken as limiting. In the next frame, the bottom plate of the sampling capacitor may be left floating (such as by opening of the switch S2 324), whereas, the top-plate may sample the pixel voltage. In some embodiments, the floating bottom plate of the capacitor (node VC 340) may lag the top plate of the capacitor and may store the difference in voltage (e.g., difference voltage) between the two consecutive frames, which may be further offset by a constant voltage of 0.5V_{DD} 326. In some embodiments, the difference voltage (which may correspond to the intensity or contrast change for a given pixel between two consecutive frames) on the bottom-plate of the sampling capacitor 328 may then be compared to a threshold using the THRESHOLDING circuit 350 (which may be implemented using two transistor comparators). The THRESHOLDING circuit 350 may generate a spike through the ON (OFF) channel if the light intensity has increased (decreased) between two consecutive frames. In some embodiments, an array of contrast-sensitive APS pixels may operate synchronously (such as when the V_{COMP} is HIGH) generating a bipolar-spike for changes in light intensity between two consecutive frames.

In some embodiments, the DVS-based contrast-sensitive pixel circuit may be implemented such as as-shown in (FIG. 3B). In some embodiments, a logarithmic photoreceptor may transduce the incident light into a logarithmic output voltage 362. In some embodiments, similar to the APS-based circuit, the source follower buffer (X1) 320 may isolate the sensitive pixel node and a following difference amplifier 370. In some embodiments, the difference amplifier 370 may be implemented as a capacitive feedback amplifier that may calculate the gradient of voltage corresponding to incident light intensity change, such as in an asynchronous manner. In some embodiments, the output voltage from the difference amplifier may then be compared in the THRESHOLDING circuit 350, which may be is similar to the APS-based circuit and generates the ON/OFF bipolar-spike.

FIG. 3C is a representative diagram of the timing waveform of the retinal bipolar functionality using APS and DVS Pixels. FIG. 3C presents a representative timing waveform of the APS pixel-based bipolar-spike generation circuit, according to one or more embodiments. I_{PD} 380 may represent the photodetector current corresponding to the incident light, and PIXEL_{OUT} 384 may refer to the ON/OFF bipolar-spike output, such as output from the pixel circuit. V_{COMP} 382 may enable a comparison between two consecutive frames with a period of T (depends on the video frame rate). V_{COMP} 382 may instead be another timing mechanism. It may be observed from the figure that when the photodetector current (corresponding light intensity) difference in both directions is higher (lower) than a threshold I_{TH} 386, PIXEL_{OUT} 384 may generate a high 388 (low 390) signal output and that is updated according to the frame rate 392 of V_{COMP} 382. Only the waveform of the APS pixel-based circuit has been shown (as most of today's commercial cameras are using the APS pixel). However, in some embodiments, the timing waveform of the DVS pixel-based circuit may operate similarly to the APS pixel-based circuit (such as as-shown in FIG. 3C), except that DVS pixels may generate asynchronous spikes (e.g., in PIXEL_{OUT} 384).

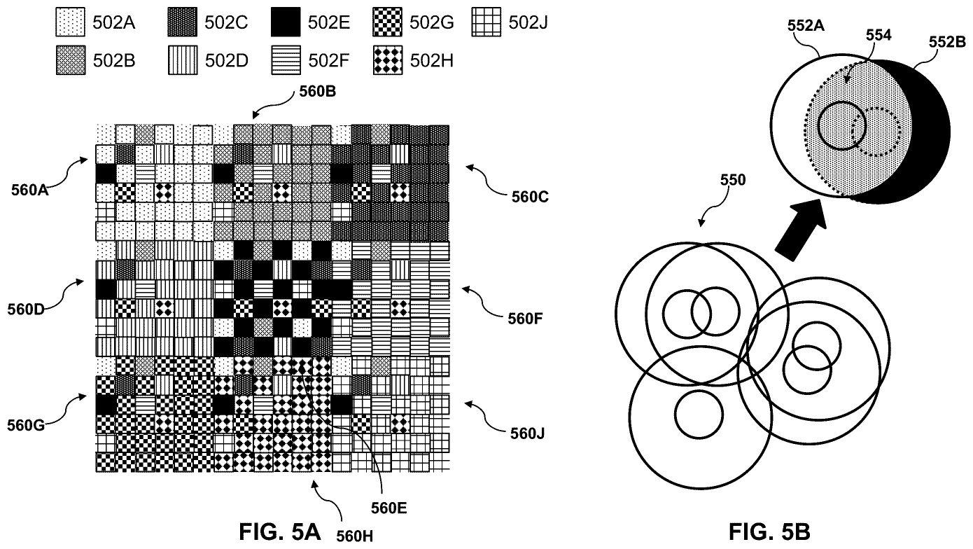

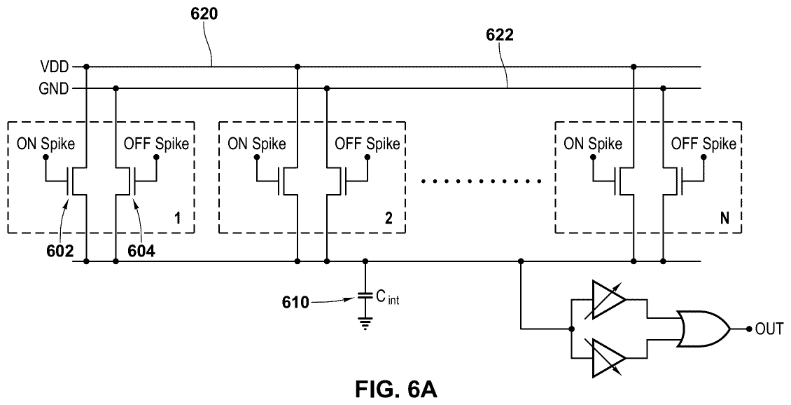

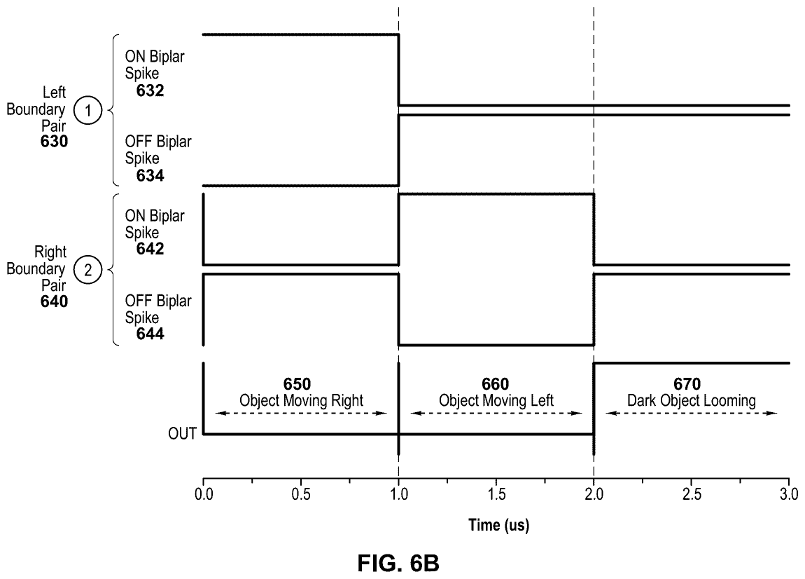

FIG. 4A is a representational diagram of a CMOS implementation of the OMS circuit. In some embodiments, the bipolar-spikes generated from each pixel (either APS-based or DVS-based) may be further processed by the circuit shown in FIG. 4A, which may implement the functionality of amacrine and ganglion cells for generation of OMS-feature-spikes. The circuit of FIG. 4A may consist of two groups of transistors, those belonging to the center region 400 (transistors M_{Ci} 404) and those belonging to the surround region 410 (transistors M_{Si} 414) in the receptive field. The gates 406 (416) of the center (surround) region transistors M_{Ci} 404 (M_{Si} 414) may be driven by bipolar-spikes 402 (412) generated from pixels belonging to the center region 400 (surround region 410). Further, in some embodiments, the upper terminal (drain) of the center region transistors may be connected to supply voltage V_{DD} 408, while the upper terminal (source) of the surround region transistors may be connected to ground GND 418. This may ensure when a particular center transistor M_{Ci} 404 receives a bipolar-spike, it may be switched ON and may integrate charges on capacitor Cᵢₙₜ 420. In some embodiments, higher numbers of bipolar-spikes generated from the center region may result in higher voltage on the capacitor Cᵢₙₜ 420. Conversely, in some embodiments, when a specific transistor M_{Si} 414 receives a bipolar-spike from surround region 410, it may turn ON and attempt to drain the charge stored on the capacitor Cᵢₙₜ 420 through the ground terminal GND 418. In some embodiments, higher numbers of bipolar-spikes received by the surround transistors M_{Si} 414 may result in lower voltage on the capacitor Cᵢₙₜ 420. In some embodiments, the group of transistors M_{Ci} 404 and M_{Si} 414 may form a voltage divider that dictates the resultant voltage on Cᵢₙₜ 420. The voltage on Cᵢₙₜ 420 may drive a high-skewed CMOS buffer 422, which may generate a spike if the voltage on Cᵢₙₜ 420 exceeds the threshold voltage (or the trip-point) of the CMOS buffer 422.

In some embodiments, when the pixels in the center region 400 generate bipolar-spikes, while at the same time, pixels in the surround region 410 also generate bipolar-spikes, it may indicate that the receptive field comprising of the center region 400 and the surround region 410 is experiencing global or background motion without any object motion. In such a case, the voltage accumulated on the capacitor Cᵢₙₜ 420 from center pixels may be offset by the discharge effect of surround pixels and the CMOS buffer 422 output may remain low. In some embodiments, if the center pixels receive bipolar-spikes, without significant corresponding bipolar-spikes on the surround pixels, the voltage accumulated on the capacitor Cᵢₙₜ 420 may not experience a significant discharging path through the surround pixels, which may result in higher voltage that pulls the output of the CMOS buffer 422 high. The generated spike from the CMOS buffer 422, thus, represents the output OMS-feature-spike, which may indicate an object motion detected in the center region with respect to the surround region.

FIG. 4B is a representational diagram of a waveform of the voltage of Cᵢₙₜ and OUT (e.g., PIXEL_{OUT}) with varying numbers of ON pixels in the Center Region of the implementation of FIG. 4A and FIG. 4C is a representational diagram of a Timing waveform with one Center and one Surround Pixel of the implementation of FIG. 4A. Timing waveforms which may be obtained by simulation of the proposed OMS circuit based on APS pixels on an advanced semiconductor node are shown in FIG. 4B-4C, according to one or more embodiments. For ease of illustration purposes, the representational diagram of FIG. 4B assumes all the center transistors M_{Ci} have received a bipolar-spike and hence are ON. The surround transistors M_{Si} are made ON such that 10% of surround transistors are ON initially and then the number of ON surround transistors increase by 10% (as shown by depicted percentages) until all the surround transistors are ON. The resulting voltage at the node Cᵢₙₜ is shown as line 430. According to one or more embodiments, the voltage on node Cᵢₙₜ decreases as higher percentage of surround transistors are switched ON. According to one or more embodiments, when sufficient surround transistors are ON the voltage at the node Cᵢₙₜ is pulled low enough (e.g., lower than threshold voltage V_{TH} 432) to result in a low voltage at the buffer output (e.g., as shown for output signal OUT 434).

In some embodiments, the design aspects of the OMS circuit, such as the circuit proposed in FIG. 4A, may be connected to aspects of a corresponding retinal-analog OMS circuit, such as the circuits of FIG. 2A. The amacrine cells pool over larger surround area as compared to the center area. In some embodiments, this may correspond to a higher number of surround transistors M_{Si} compared to the center transistors M_{Ci}. In some embodiments, pooling spikes from multiple pixels in the surround region may be ensured, such as in circuit shown in FIG. 4A, where the surround pixels when activated drive the same capacitance Cᵢₙₜ. Further, in some embodiments, since the surround region may be significantly larger than the center region, the spikes generated from the surround region (such as surround pixel spike 440 of FIG. 4C) may need to be appropriately weighted by the synaptic-analog connections to ensure proper OMS functionality (e.g., to balance with the center pixel spike 442 of FIG. 4C). In some embodiments, such as in the circuit of FIG. 4A, this may be ensured by designing surround transistors M_{Si} with lower transistor widths as compared to the center transistors M_{Ci}. Finally, as shown in FIG. 2A, the synaptic-analog connections between amacrine cells from the surround region and the RGC may be inhibitory in nature, while the synaptic connections between bipolar-cells in the center region and the RGC may be excitatory in nature. In some embodiments, inhibitory and excitatory connections may be ensured by connecting the drain of center pixels to V_{DD} and the source of surround pixels to ground.

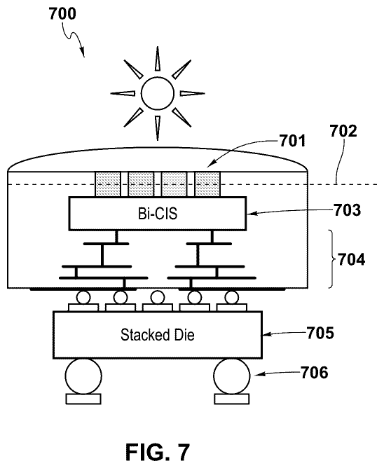

FIGS. 5A-5B are representational diagrams of implementation of center-surround receptive field in a 2D array of pixels and biological receptive fields corresponding to neighboring ganglion cells to which the pixel array is analogous, respectively. The center-surround receptive field necessary for OMS functionality may be implemented, such in image sensors as shown in FIGS. 5A-5B, according to one or more embodiments. FIG. 5A shows a two-dimensional array of pixels, of types 502A-502J. It is important to note that state-of-the-art cameras may consist of millions of pixels constituting the focal plane array. In some embodiments, the pixel array may be divided into multiple regions, such as regions 560A-560J, each containing a majority of a corresponding pixel type of types 502A-502J. In some embodiments, each individual region may act as a center region, with or without a separate surround region. For example, FIG. 5A shows the pixel array consisting of 9 center regions labelled A through J (label I has been skipped so that it is not confused with numeral 1). Consider a specific center region, say region E (e.g., region 560E). The surround region corresponding to the center region E (e.g., region 560E) may be implemented as pixels (e.g., of type 502E) that are interleaved in the neighboring center regions (e.g., regions 560A-560D and 560F-560J). In FIG. 5A, the pixels corresponding to the center region E (e.g., region 560E) are represented in solid black (e.g., within the region E). The surround pixels corresponding to the center region E (e.g., region 560E) are depicted as solid black pixels embedded in the regions A through J (e.g., region 560A-D and regions 560F-560J) except E (e.g., region 560E). In some embodiments, for the entire array of pixels, each center region may consist of majority of pixels constituting its own center region and fewer interleaved pixels that would correspond to the surround region of neighboring center regions. Note, in FIG. 5A the surround pixel interleaving is shown explicitly for all the pixels in the center region E (e.g., region 560E), while it is only shown partially for the center region A through J (e.g., region 560A-D and regions 560F-560J) except E (e.g., region 560E), for visual clarity. As shown in FIG. 5A, receptive fields 550 of retinal ganglion cells (RGCs) may overlap extensively. Two overlapping receptive fields are shown for a first ganglion 552A and a second ganglion 552B, where the overlap is shown as region 554. The 2D array of FIG. 5A may be an analog of the overlapping receptive fields 550 of FIG. 5B.

In some embodiments, the method mimicking the center-surround receptive field (such as shown in FIGS. 5A-5B) may be amenable to implementation in state-of-the-art high-resolution cameras that inherently consists of numerous high-density pixels. Furthermore, in some embodiments, the metal wires and transistors needed for routing signals between center and corresponding surround regions may be implemented using the back-end-of-line metal layers and front-end-of-line transistors from the sensor and processing die, respectively, such as represented in FIG. 1B. In some embodiments, the backside illuminated CMOS sensor and/or the heterogeneously integrated processing chip may allow transistors and photodiodes to be integrated on top of a senor chip (which receives incident light) and the another set of transistors may be fabricated towards the bottom of the processing chip, with several layers of metals between them. In some embodiments, such a structure is naturally amenable to complex routing of signals as implemented by center-surround receptive field for OMS functionality.

### Embedding LD Functionality in Image Sensors

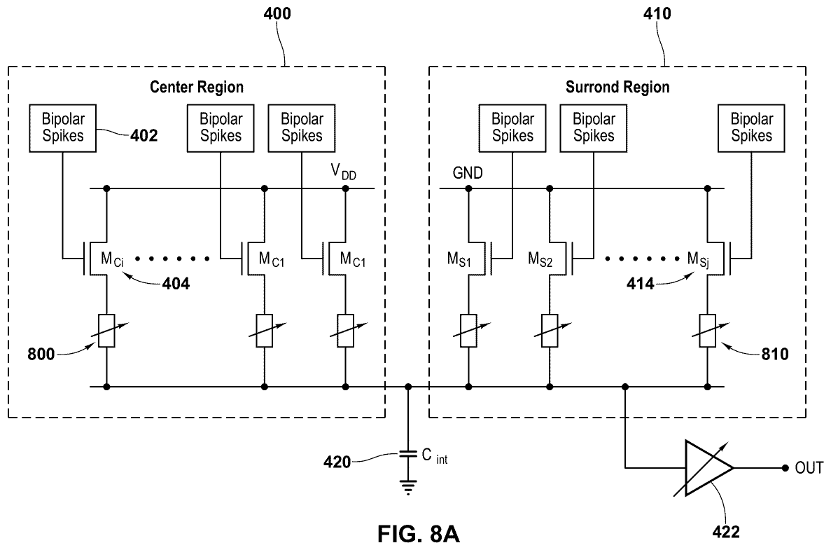

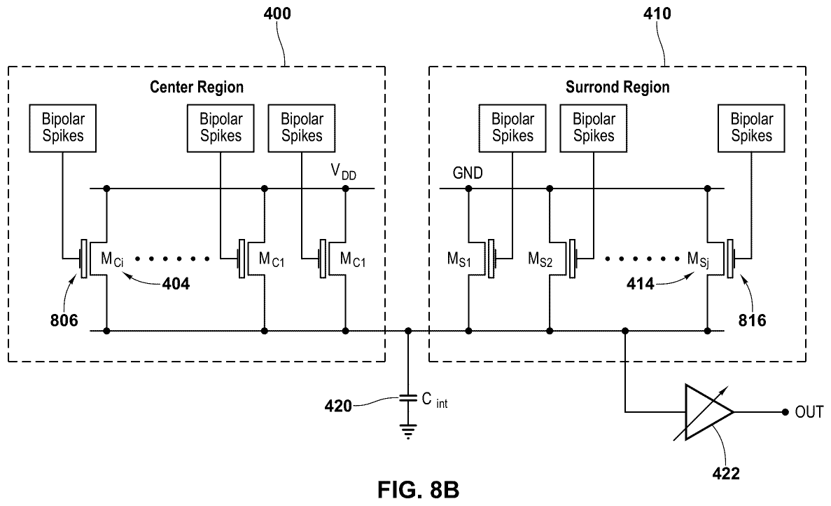

FIG. 6A is a representational diagram of CMOS implementation of Looming Detection Circuit diagram and FIG. 6B is a representational diagram of a Timing Waveform of the retinal Looming functionality showing the output voltage in three different scenarios for the implementation of FIG. 6A. A solid-state implementation of retinal LD circuit from FIG. 2B, according to one or more embodiments is shown in FIG. 6A. The figure consists of multiple pair of transistors (e.g., ON spike transistor 602 and OFF spike transistor 604) connected to a common capacitor Cᵢₙₜ 610. The upper terminal (drain) of the ON spike transistors are connected to V_{DD} 620, while the upper terminal (source) of the OFF spike transistors are connected to ground GND 622. Further, the gate of ON spike transistors are driven by ON bipolar-spikes and the gates of OFF spike transistors are driven by OFF bipolar-spikes. Consider a dark object laterally moving in the receptive field. In some embodiments, no bipolar-spikes would be generated from those pixels in the receptive field that correspond to the internal region of the dark object. This may be because bipolar-spikes may only be generated in response to change in light contrast. The internal region (or the body) of the dark object may continuously present low light intensity and hence may not excite any bipolar-spikes. In contrast, in some embodiments, pixels at the boundary of the object may experience contrast change as the object moves laterally. Specifically, if the dark object is moving to the right, in reference to FIG. 6A, the pair of ON spike and OFF spike transistors at the left boundary of the object may experience change in light contrast. As the dark object moves to the right, the corresponding pixel pair (e.g., at the left edge of the dark object) may experience an increase in light intensity, and a corresponding ON bipolar-spike may then be generated. The ON bipolar spike may activate the ON spike transistor (e.g., among the pair of transistors) at the left boundary of the object. Similarly, on the right boundary of the object an OFF spike may be generated as the pixels at the right boundary may experience decrease in light intensity as the object moves to the right. Consequently, an OFF bipolar-spike may be generated (e.g., at the leading edge of the dark object). The ON spike transistor connected to the ON bipolar-spike at the left boundary of the (right-moving) object may act to pull up the voltage on the capacitor Cᵢₙₜ 610, while the OFF spike transistor receiving the OFF bipolar-spike on the right may act to pull down the voltage on the capacitor. In some embodiments, this may result in voltage on capacitor Cᵢₙₜ 610 close to V_{DD}/2. In some embodiments, the logic circuit connected to the capacitor Cᵢₙₜ 610 may be designed to generate a low output when the voltage on Cᵢₙₜ 610 is close to V_{DD}/2. In some embodiments, the output of the logic circuit may be high only when the voltage on Cᵢₙₜ 610 deviates significantly from V_{DD}/2 (i.e., either is closer to V_{DD} or closer to ground). In accordance with some embodiments, the logic circuit may generate a low output in response to a voltage of V_{DD}/2 on node Cᵢₙₜ 610 as the object moves to the right. In some embodiments, similar argument holds true when an object in the receptive field moves to the left, resulting in a low response from the logic circuit.

As seen in FIG. 6B, a left boundary pair 630 may consist of a ON bipolar spike transistor 632 and an OFF bipolar spike transistor 634 and a right boundary pair 640 may consist of a ON bipolar spike transistor 642 and an OFF bipolar spike transistor 644. An object moving right (e.g., in time frame 650) may result in a low signal from the ON bipolar spike transistor 642 and a high signal from the OFF bipolar spike transistor 644 from the right boundary pair 640, and a high signal from the ON bipolar spike transistor 632 and a low signal from the OFF bipolar spike transistor 634 from the left boundary pair 630. This may correspond to a transient spike in an OUT 680 current of a circuit containing both the left boundary pair 630 and the right boundary pair 640. The transient spike may resolve to a low OUT 680 current, once the object has been detected.

An object moving left (e.g., in time frame 660) may result in a low signal from the ON bipolar spike transistor 632 and a high signal from the OFF bipolar spike transistor 634 from the left boundary pair 630, and a high signal from the ON bipolar spike transistor 642 and a low signal from the OFF bipolar spike transistor 644 from the right boundary pair 640. This may correspond to a transient spike in the OUT 680 current of a circuit containing both the left boundary pair 630 and the right boundary pair 640. The transient spike may resolve to a low OUT 680 current, once the object has been detected.

A looming object (e.g., in time frame 670) may result in may result in a low signal from the ON bipolar spike transistor 632 and a high signal from the OFF bipolar spike transistor 634 from the left boundary pair 630, and a low signal from the ON bipolar spike transistor 642 and a high signal from the OFF bipolar spike transistor 644 from the right boundary pair 640. This may correspond to a transient dip in the OUT 680 current of a circuit containing both the left boundary pair 630 and the right boundary pair 640. The transient dip may resolve to a high OUT 680 current, once the object has been detected.

In a further example, consider the dark object within the receptive field which may be approaching (or looming). In some embodiments, in such a case, the pair of transistors on the left and the right boundary of the object may simultaneously experience decrease in light intensity (e.g., as the boundary of the dark object expands), thereby generating OFF bipolar-spikes. The OFF spike transistors at the left and the right boundary may be activated by the OFF bipolar spikes, while all the other transistors may remain OFF. In some embodiments, therefore, the boundary OFF spike transistors may pull the voltage across Cᵢₙₜ low. In some embodiments, in response to a low voltage on Cᵢₙₜ 610 the logic circuit may generate a high output voltage (or an LD feature-spike) indicating an approaching or looming object in the receptive field. In some embodiments, instead of a dark object the LD circuit may also generate an LD feature-spike if a bright object is approaching in the receptive field. For example, in this case, the ON spike transistors at the left and right boundary of the object may be active (as depicted in FIG. 6A), the node voltage on Cᵢₙₜ 610 may increase closer to V_{DD} 620 and the logic circuit may respond by generating a high output.

In some embodiments, IRIS sensors may embed retinal feature extraction behavior using retina-inspired circuits within image sensors. In some embodiments, similar circuit-technology design techniques (e.g., similar to OMS and LD) may be used to embed a rich class of retinal functionality including color, object orientation, object shape, etc. in image sensors. In some embodiments, IRIS sensors can be implemented based on underlying APS or DVS pixels. In some embodiments, for APS pixels to achieve high dynamic range a coarse grained (at pixel-array-level) or fine-grained (at individual pixel level) exposure timing control may be implemented. In some embodiments, the photodiodes associated with IRIS sensors may span wide range of wavelengths including visible light, infra-red, or near infra-red light.

In some embodiments, advances in 3D integration of semiconductor chips may enable IRIS sensors. In some embodiments, 3D integration may allow integration of routing metal layers and transistor-based circuits required from implementing spatio-temporal computations similar to retinal circuit directly above (or under) the pixel array. Such 3D integrated IRIS sensors may use various 3D packaging technologies like metal-to-metal fusion bonding, through silicon vias (TSVs), etc. Further, heterogeneous sensors operating at different wavelengths may be co-integrated to extract retina-like feature vectors over different spectrums of light.

In some embodiments, IRIS sensors may have a significant impact on computer vision. Today's computer vision may rely exclusively on light intensity-based (APS) or light change-detection-based (DVS) pixels data collected through state-of-the-art CMOS image sensors. However, in almost all cases, appropriate context for the pixels may be missing (or may be extremely vague) with respect to the ‘real-world events’ being captured by the sensor. Thus, the onus of processing may be put on intelligent machine learning algorithms to pre-process, extract appropriate context, and make intelligent decisions based on pixel data. Unfortunately, such a vision pipeline may lead to 1) complex machine learning algorithms designed to cater to image/video data without appropriate context 2) increases the time to decision, associated with the processing time of the machine learning algorithms 3) energy-hungry and slow access to pixel data being captured and generated by the CMOS image sensor. In some embodiments, IRIS sensors may usher in new frontiers in vision-based decision making by generating highly specific motion and shape-based features, providing valuable context to pixels captured by the camera. In some embodiments, the underlying algorithms processing data generated from IRIS sensors may be based on traditional deep learning models or on emerging set of spiking neural networks that could process feature-spikes generated from IRIS sensors. In some embodiments, since IRIS cameras may use APS pixels, in general, they may generate both feature-spikes and light intensity map as and when required by the computer vision algorithms.

### Fabrication

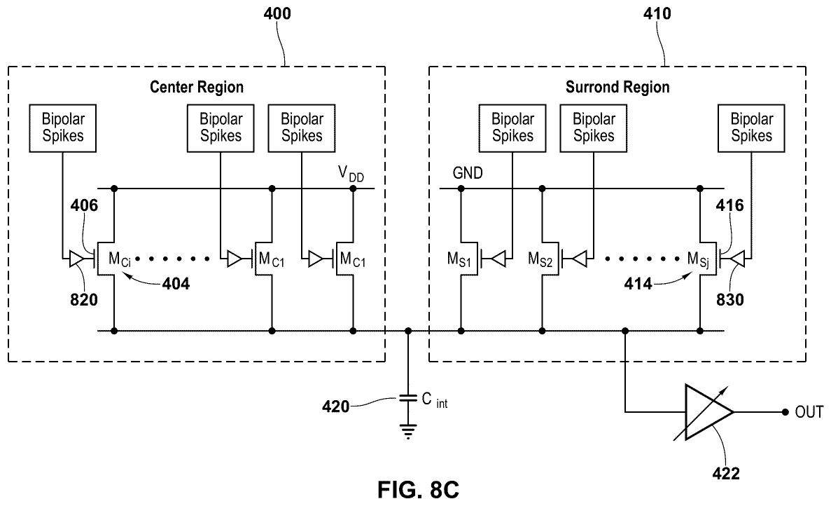

FIG. 7 is a representational illustration of heterogeneously integrated IRIS system 700, built on backside illuminated CMOS image sensor (Bi-CIS), with elements including micro lens 701, light shield 702, backside illuminated CMOS Image Sensor (Bi-CIS) 703, backend of line of the Bi-CIS 704, stacked die 705, solder bumps 706 for input/output bus (I/O), according to one or more embodiments n some embodiments, IRIS sensors may be manufacturable using existing foundry processes. A representative illustration of a heterogeneously integrated system catering to the needs of presented proposal, according to one or more embodiments, is shown in FIG. 7. The figure consists of two key elements, i) backside illuminated CMOS image sensor (Bi-CIS) 703, consisting of photodiodes, and bipolar cell functionality, and ii) a 3D stacked die 705 consisting of circuits representing amacrine and ganglion cell functionality. In some embodiments, the Bi-CIS chip may be implemented in a leading or lagging technology node. In some embodiments, the die consisting of amacrine and ganglion cells may be built on an advanced planar or non-planar technology node. In some embodiments, the Bi-CIS image sensor chip/die may be heterogeneously integrated through a bonding process (die-to-die or die-to-wafer) integrating it onto the 3D stacked die. In some embodiments, a die-to-wafer low-temperature metal-to-metal fusion with a dielectric-to-dielectric direct bonding hybrid process may be preferably achieved high-throughput sub-micron pitch scaling with precise vertical alignment. In some embodiments, this heterogeneous integration technology may allow chips of different sizes to be fabricated at distinct foundry sources, technology nodes, and functions and then integrated together, which may present an advantage for fabrication. In some embodiments, the through silicon via (TSV) integration technique for front-side illuminated CMOS image sensor (Fi-CIS) may be adopted, wherein the CMOS image sensor may be bonded onto the die consisting of amacrine and ganglion functionality through a TSV process. In some embodiments, copper to copper bonding may be used to bond electrically active areas of a Bi-CIS to electrically active areas of one or more die containing processing circuity, such as the 3D stacked die 705. In some embodiments, any appropriate method of three-dimensional integration may be used. In some embodiments, in contrast to some other TSV technology, in the Bi-CIS, the wiring may be moved away from the illuminated light path allowing more light to reach the sensor, giving better low-light performance.

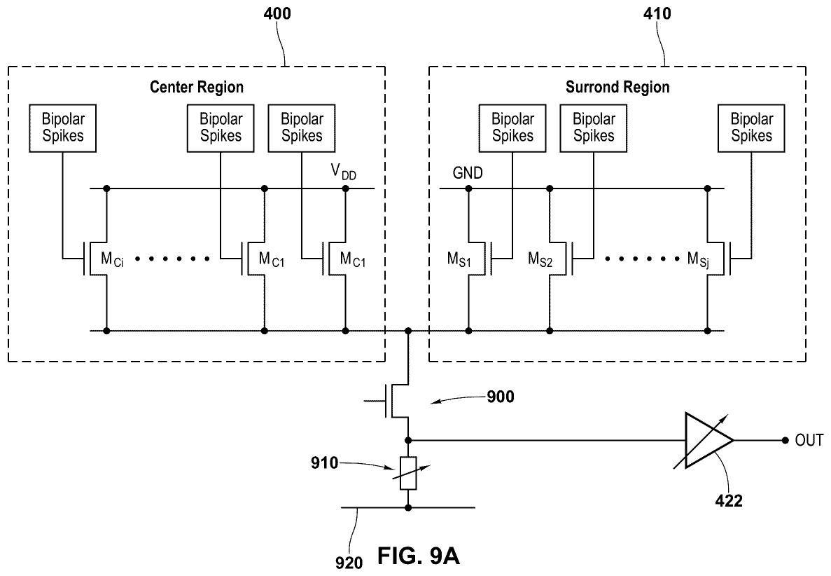

FIGS. 8A-8C are representational diagrams of CMOS implementation of the OMS circuit with various types of in-circuit memory. FIGS. 8A-8C are described with reference to elements previously identified and described in reference to FIG. 4A. FIG. 8A is a representational diagram of the CMOS implementation of the OMS circuit with additional two terminal memory circuity for each bipolar signal device. In one or more embodiments, memory may be incorporated into the OMS circuit. The addition of memory in an image circuit, which may be present in addition to circuitry for performing processing such as through the bipolar spike circuity, may provide for additional processing more in one or more embodiments. For example, center (surround) region transistors M_{Ci} 404 (M_{Si} 414) may be driven by bipolar-spikes 402 (412) generated from pixels belonging to the center region 400 (surround region 410). The output of the center (surround) region transistors M_{Ci} 404 (M_{Si} 414) may be weighted by input into a memory circuit 800 (810), such as a two terminal (2T) non-volatile memory (NVM) memory device. For example, the output of the center (surround) region transistors M_{Ci} 404 (M_{Si} 414) may be input into a resistive random-access memory (resistive RAM or RRAM), phase-change memory (PCM), magneto resistive RAM (MRAM), ferroelectric RAM (FeRAM), correlated electron RAM (CERAM), etc. memory circuit 800 (810). A signal from the center (surround) region transistors M_{Ci} 404 (M_{Si} 414) may be output into the memory circuit 800 (810), which may be writable through a write line and write the device. A signal from the center (surround) region transistors M_{Ci} 404 (M_{Si} 414) may be output into the memory circuit 800 (810), which may be readable though an input and read the device. A signal from the center (surround) region transistors M_{Ci} 404 (M_{Si} 414) may be output into the memory circuit 800 (810) and output of the center (surround) region transistors M_{Ci} 404 (M_{Si} 414) may be weighted according to a value stored in the memory circuit. A signal from the center (surround) region transistors M_{Ci} 404 (M_{Si} 414) may be output into the memory circuit 800 (810) and a value corresponding to the signal from the center (surround) region transistors M_{Ci} 404 (M_{Si} 414) may be stored in the memory circuit 800 (810), including for later reading. Values stored on the memory circuit 800 (810) may be non-volatile and may have a lifetime longer than a refresh rate (e.g., frame rate) of the image circuit. Values stored on the memory circuit 800 (810) may be refreshed at the refresh rate (e.g., frame rate) of the image circuit. A signal from a first frame of the center (surround) region transistors M_{Ci} 404 (M_{Si} 414) may be stored in the memory circuit 800 (810) during a write period in a first frame and then operated on by a signal from a second frame of the center (surround) region transistors M_{Ci} 404 (M_{Si} 414) during a second (or subsequent) frame. This may allow the OMS circuit to further select signals for pixels which experience changes in luminance over subsequent frames by selecting (and transmitting) only signals which have a nonzero value for two or more frames (such as in a row).

FIG. 8B is a representational diagram of the CMOS implementation of the OMS circuit with additional three terminal memory circuity for each bipolar signal device. In one or more embodiments, memory may be incorporated into the OMS circuit, including into other circuit elements (such as transistors) of the OMS circuit. The addition of memory within the image circuit may provide for additional processing more in one or more embodiments. For example, center (surround) region transistors M_{Ci} 404 (M_{Si} 414) may be driven by bipolar-spikes 402 (412) generated from pixels belonging to the center region 400 (surround region 410). The center (surround) region transistors M_{Ci} 404 (M_{Si} 414) may include memory circuity or be a part of a memory circuity. For example, the center (surround) region transistors M_{Ci} 404 (M_{Si} 414) may be part of a memory circuity 806 (816), such as a three terminal (3T) non-volatile memory (NVM) memory device. The bipolar spikes may drive a gate of the center (surround) region transistors M_{Ci} 404 (M_{Si} 414), which may be memory circuits 806 (816) such as ferroelectric field effect transistors (ferroelectric FETS or FeFETs), charge trap transistors (CTT), etc. The output of the center (surround) region transistors M_{Ci} 404 (M_{Si} 414) may be weighted output of the memory circuit 806 (816). A bipolar spike may write to the memory circuit 806 (816). A bipolar spike may read from the memory circuit 806 (816). A bipolar spike may turn on the memory circuit 806 (816), such as by application of a gate voltage, which may allow current (or voltage) to flow from V_{DD} or to GND. A bipolar spike may weigh an output of the memory circuit 806 (816), such as by functioning as an amplification signal to the memory circuit 806 (816). A bipolar spike signal may be stored in the memory circuit 806 (816), such as for subsequent reading. Values stored on the memory circuit 806 (816) may be non-volatile and may have a lifetime longer than a refresh rate (e.g., frame rate) of the image circuit. Values stored on the memory circuit 806 (816) may be refreshed at the refresh rate (e.g., frame rate) of the image circuit. A bipolar spike from a first frame of an image sensor may be stored in the memory circuit 806 (816) during a write period in a first frame and then operated on by a signal (e.g., of a bipolar spike) from a second frame during a second (or subsequent) frame. This may allow the OMS circuit to further select signals for pixels which experience changes in luminance over subsequent frames by selecting (and transmitting) only signals which have a nonzero value for two or more frames (such as in a row).

FIG. 8C is a representational diagram of the CMOS implementation of the OMS circuit with additional signal conditioning circuitry for each bipolar signal device. In one or more embodiments, signal conditioning (such as amplification, thresholding, etc.) may be incorporated into the OMS circuit. The addition of signal conditioning in an image circuit, which may be present in addition to circuitry for performing processing such as through the bipolar spike circuity, may provide for additional signal processing more in one or more embodiments. For example, center (surround) region transistors M_{Ci} 404 (M_{Si} 414) may be driven by bipolar-spikes 402 (412) generated from pixels belonging to the center region 400 (surround region 410). The input to the center (surround) region transistors M_{Ci} 404 (M_{Si} 414) may be conditioned by one or more amplifier 820 (826), such as before being fed to the center (surround) region transistors M_{Ci} 404 (M_{Si} 414). In one or more embodiments, signal conditioning may include thresholding, smoothing, a delay line, etc. In one or more embodiments, signal conditioning may occur at one or more points before the bipolar spike signals are fed to the center (surround) region transistors M_{Ci} 404 (M_{Si} 414). For example, signal conditioning may occur closer to the photodetector than the center (surround) region transistors M_{Ci} 404 (M_{Si} 414), closer to the center (surround) region transistors M_{Ci} 404 (M_{Si} 414) than the photodetector, etc. Conditioning of a signal, such as a bipolar spike signal, may allow for small signals to be amplified (so as to be included in calculations), for small signals to be excluded (such as by thresholding), for signal synchronization, desynchronization (such as for frame separation), etc. Conditioning of the signal may include weighting of signals, and may thereby include processing operations. For example, bipolar spike signals of some types of pixels may be amplified while others are not, where amplification factors may represent weightings, such as weightings corresponding to parameters of a portion of a neural network or other computing process.

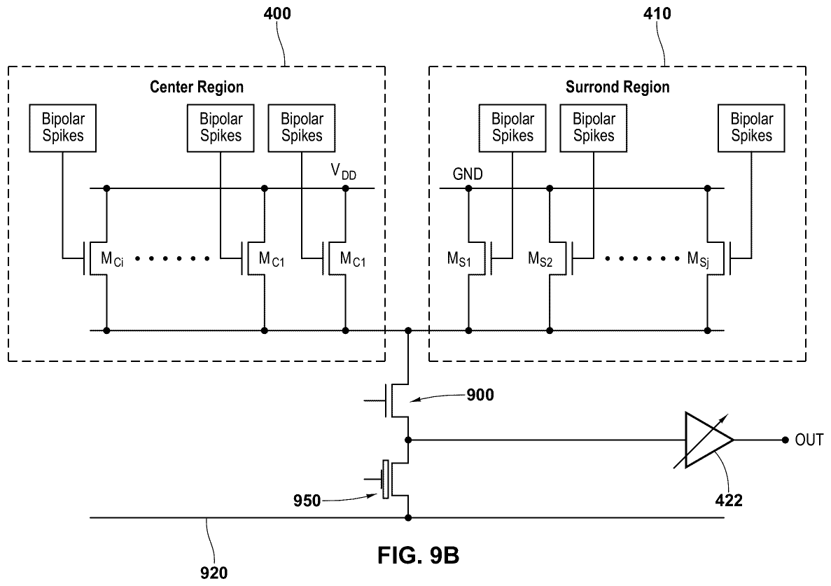

FIGS. 9A-9B are representational diagrams of CMOS implementation of the OMS circuit with various types of memory integrated into charge integration circuity. FIGS. 9A-9B are described with reference to elements previously identified and described in reference to FIG. 4A. FIG. 9A is a representational diagram of the CMOS implementation of the OMS circuit with additional memory and a selector element in place of Cᵢₙₜ (as depicted in FIG. 4A). In one or more embodiments, the additional memory and the selector element may function as a collector or comparator for determining when the OMS circuit may output a signal. For example, an output of the transistors M_{Ci} 404 of the center region 400 and the transistors M_{Si} 414 of the surround region 410 may be collected at the selector transistor 900. The selector transistor 900 may be controlled by a selector signal, such as applied to its gate. The selector transistor 900 may output a signal to a 2T NVM memory circuit 910, such as previously described in reference to FIG. 8A. The memory circuit 910 may receive input (or output) from a source line 920. The output from the selector transistor 900 may preferentially drain to the source line 920 or output to the CMOS buffer 422, based on the setting of the memory circuit 910. The memory circuit 910 may therefore act as a thresholding element for the selector transistor 900. In some embodiments, the output of the selector transistor 900 may write to, read from, or perform another function for the memory circuit 910, such as described for the memory circuit 800 (810) of FIG. 8A.

FIG. 9B is a representational diagram of the CMOS implementation of the OMS circuit with additional memory and a selector element in place of Cᵢₙₜ (as depicted in FIG. 4A). In one or more embodiments, the additional memory and the selector element may function as a collector or comparator for determining when the OMS circuit may output a signal. For example, an output of the transistors M_{Ci} 404 of the center region 400 and the transistors M_{Si} 414 of the surround region 410 may be collected at the selector transistor 900. The selector transistor 900 may be controlled by a selector signal, such as applied to its gate. The selector transistor 900 may output a signal to a 3T NVM memory circuit 950, such as previously described in reference to FIG. 8B. The memory circuit 950 may receive input (or output) from a source line 920. The memory circuit 950 may be written to, cause to read, or otherwise be controlled by a control line (e.g., by application of a gate voltage to the memory circuit 950). The output from the selector transistor 900 may preferentially drain to the source line 920 or output to the CMOS buffer 422, based on the setting of the memory circuit 950. The memory circuit 950 may therefore act as a thresholding element for the selector transistor 900. In some embodiments, the output of the selector transistor 900 may write to, read from, or perform another function for the memory circuit 940, such as described for the memory circuit 800 (810) of FIG. 8B.

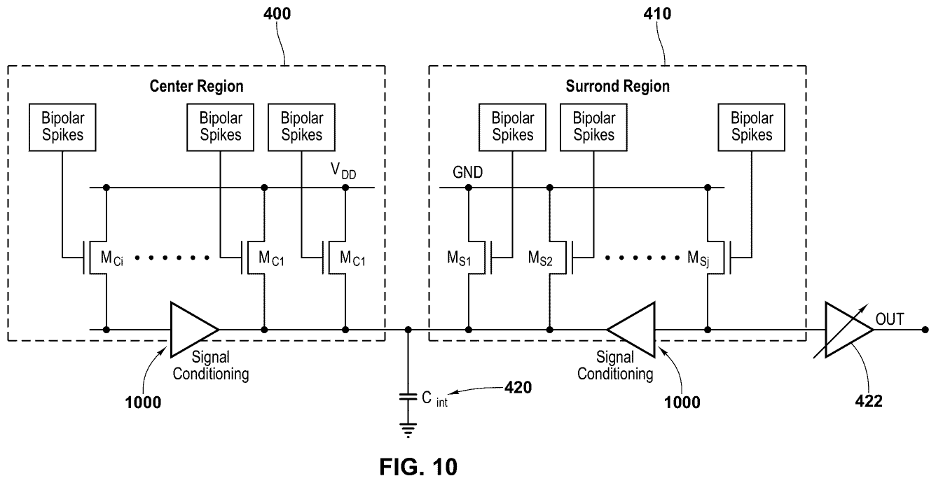

FIG. 10 is a representational diagram of CMOS implementation of the OMS circuit with signal conditioning. FIG. 10 is described with reference to elements previously identified and described in reference to FIG. 4A. In one or more embodiments, signal conditioning (such as amplification, thresholding, etc.) may be incorporated into the OMS circuit. The addition of signal conditioning in an image circuit, which may be present in addition to circuitry for performing processing such as through the bipolar spike circuity, may provide for additional signal processing more in one or more embodiments. For example, center (surround) region transistors M_{Ci} 404 (M_{Si} 414) may be driven by bipolar-spikes 402 (412) generated from pixels belonging to the center region 400 (surround region 410). The output of the center (surround) region transistors M_{Ci} 404 (M_{Si} 414) may be conditioned by one or more amplifier 1000 or other signal conditioner, such as before being fed to the capacitor Cᵢₙₜ 420. In one or more embodiments, signal conditioning may include thresholding, smoothing, a delay line, etc. In one or more embodiments, signal conditioning may occur at one or more points before the output of the center (surround) region transistors M_{Ci} 404 (M_{Si} 414) are added, such as by weighting the output of some of the center (surround) region transistors M_{Ci} 404 (M_{Si} 414) (and not others). Conditioning of a signal, such as output of the center (surround) region transistors M_{Ci} 404 (M_{Si} 414), may allow for small signals to be amplified (so as to be included in calculations), for small signals to be excluded (such as by thresholding), for signal synchronization, desynchronization (such as for frame separation), etc. Conditioning of the signal may include weighting of signals, and may thereby include processing operations. For example, output of some of the center (surround) region transistors M_{Ci} 404 (M_{Si} 414) may be amplified while others are not, where amplification factors may represent weightings, such as weightings corresponding to parameters of a portion of a neural network or other computing process.

FIGS. 8A-8C, 9A-9B, and 10 are described in relation to an OMS circuit, but analogous memory elements may be integrated into LD or other vision circuits based on the same principles.

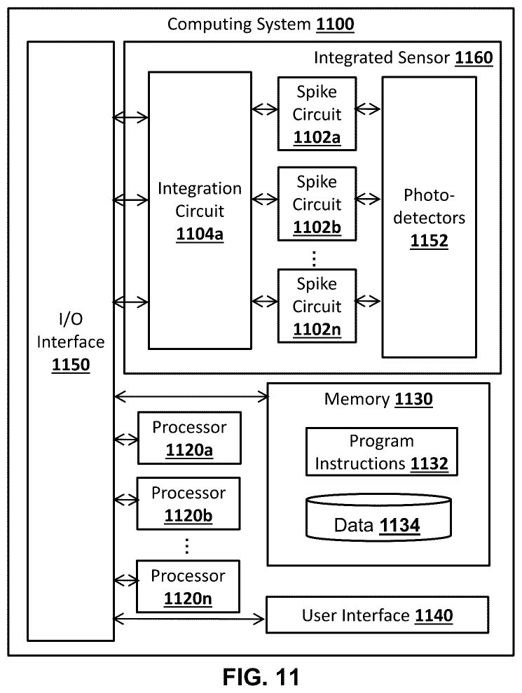

FIG. 11 illustrates an example computing system using integrated retinal functionality in image sensors. Various portions of systems and methods described herein may include or be executed on one or more computing systems similar to computing system 1100. Further, processes and modules described herein may be executed by one or more processing systems similar to that of computing system 1100.

Computing system 1100 may include one or more processors (e.g., processors 1120a-1120n) coupled to system memory 1130, and a user interface 1140 via an input/output (I/O) interface 1150. A processor may include a single processor or a plurality of processors (e.g., distributed processors). A processor may be any suitable processor capable of executing or otherwise performing instructions. A processor may include a central processing unit (CPU) that carries out program instructions to perform the arithmetical, logical, and input/output operations of computing system 1100. A processor may execute code (e.g., processor firmware, a protocol stack, a database management system, an operating system, or a combination thereof) that creates an execution environment for program instructions. A processor may include a programmable processor. A processor may include general or special purpose microprocessors. A processor may receive instructions and data from a memory (e.g., system memory 1130). Computing system 1100 may be a uni-processor system including one processor (e.g., processor 1120a-1120n), or a multi-processor system including any number of suitable processors (e.g., 1120a-1120n). Multiple processors may be employed to provide for parallel or sequential execution of one or more portions of the techniques described herein. Processes, such as logic flows, described herein may be performed by one or more programmable processors executing one or more computer programs to perform functions by operating on input data and generating corresponding output. Processes described herein may be performed by, and apparatus can also be implemented as, special purpose logic circuitry, e.g., an FPGA (field programmable gate array) or an ASIC (application specific integrated circuit). Computing system 1300 may include a plurality of computing devices (e.g., distributed computing systems) to implement various processing functions.

Computing system 1100 may include one or more photodetectors (e.g., photodetectors 1152) or other sensors in an integrated sensor 1160. The integrated sensor 1160 may be coupled to system memory 1130, and a user interface 1140 via an input/output (I/O) interface 1150. Photodetectors 1152 may be pixels, sub-pixels, photodiodes, resistive photodetectors, etc. Photodetectors 1152 may be coupled to spike circuits 1102a-1102n, where each of the spike circuits 1102a-1102n may be coupled to one or more of the photodetectors 1152. The spike circuits 1102a-1102n may be bipolar spike circuits, such as previously described. The spike circuits 1102a-1102n may operate on outputs of the photodetectors 1152. The spike circuits 1102a-1102n may generate bipolar spikes based on some conditions (e.g., signals) or one or more of the photodetectors 1152. The spike circuits 1102a-1102n may be coupled to an integration circuit 1104, which may integrate (or accumulate) output of one or more of the spike circuits 1102a-1102n.

The spike circuits 1102a-1102n may operate on outputs of the photodetectors 1152, which may allow weighting, transmission, pass though, collection, amplification, etc. of the outputs of the photodetectors 1152. The spike circuits 1102a-1102n may select for outputs of the photodetectors 1152 corresponding specific vision sensing schemes, such as OMS or LD. The spike circuits 1102a-1102n or another computation element may contain additional memory elements, such as ROM, eDRAM, accumulation elements, etc. which may be readable or readable and writable memory. The photodetectors 1152 and spike circuits 1102a-1102n may be controlled by one or more reset element, such as a reset element (not depicted) in communication with the I/O interface 1150 or controlled by one or more of the processors 1120a-1120n. The photodetectors 1152 may be exposed to input, such as light (e.g., in the case of a photosensor) or other input, an analyte (such as temperature), or other sensing material. The photodetectors 1152 may comprise transistors, diodes, etc.

The user interface 1140 may comprise one or more I/O device interface, for example to provide an interface for connection of one or more I/O devices to computing system 1100. The user interface 1140 may include devices that receive input (e.g., from a user) or output information (e.g., to a user). The user interface 1140 may include, for example, graphical user interface presented on displays (e.g., a cathode ray tube (CRT) or liquid crystal display (LCD) monitor), pointing devices (e.g., a computer mouse or trackball), keyboards, keypads, touchpads, scanning devices, voice recognition devices, gesture recognition devices, printers, audio speakers, microphones, cameras, or the like. The user interface 1140 may be connected to computing system 1100 through a wired or wireless connection. The user interface 1140 may be connected to computing system 1100 from a remote location. The user interface 1140 may be in communication with one or more other computing systems. Other computing units, such as located on remote computer system, for example, may be connected to computing system 1100 via a network.

System memory 1130 may be configured to store program instructions 1132 or data 1134. Program instructions 1132 may be executable by a processor (e.g., one or more of processors 1120a-1120n) to implement one or more embodiments of the present techniques. Program instructions 1132 may include modules of computer program instructions for implementing one or more techniques described herein with regard to various processing modules. Program instructions may include a computer program (which in certain forms is known as a program, software, software application, script, or code). A computer program may be written in a programming language, including compiled or interpreted languages, or declarative or procedural languages. A computer program may include a unit suitable for use in a computing environment, including as a stand-alone program, a module, a component, or a subroutine. A computer program may or may not correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one or more computer processors located locally at one site or distributed across multiple remote sites and interconnected by a communication network.

System memory 1130 may include a tangible program carrier having program instructions stored thereon. A tangible program carrier may include a non-transitory computer readable storage medium. A non-transitory computer readable storage medium may include a machine-readable storage device, a machine-readable storage substrate, a memory device, or any combination thereof. Non-transitory computer readable storage medium may include non-volatile memory (e.g., flash memory, ROM, PROM, EPROM, EEPROM memory), volatile memory (e.g., random access memory (RAM), static random-access memory (SRAM), synchronous dynamic RAM (SDRAM)), bulk storage memory (e.g., CD-ROM and/or DVD-ROM, hard-drives), or the like. System memory 1130 may include a non-transitory computer readable storage medium that may have program instructions stored thereon that are executable by a computer processor (e.g., one or more of processors 1120a-1120n) to cause the subject matter and the functional operations described herein. A memory (e.g., system memory 1130) may include a single memory device and/or a plurality of memory devices (e.g., distributed memory devices). Instructions or other program code to provide the functionality described herein may be stored on a tangible, non-transitory computer readable media. In some cases, the entire set of instructions may be stored concurrently on the media, or in some cases, different parts of the instructions may be stored on the same media at different times.

I/O interface 1150 may be configured to coordinate I/O traffic between processors 1120a-1120n, spike circuits 1102a-1102n, integration circuit 1104, photodetectors 1152, system memory 1130, user interface 1140, etc. I/O interface 1150 may perform protocol, timing, or other data transformations to convert data signals from one component (e.g., system memory 1130) into a format suitable for use by another component (e.g., processors 1120a-1120n). I/O interface 1150 may include support for devices attached through various types of peripheral buses, such as a variant of the Peripheral Component Interconnect (PCI) bus standard or the Universal Serial Bus (USB) standard.

Embodiments of the techniques described herein may be implemented using a single instance of computing system 1100 or multiple computing systems 1100 configured to host different portions or instances of embodiments. Multiple computing systems 1100 may provide for parallel or sequential processing/execution of one or more portions of the techniques described herein.

Those skilled in the art will appreciate that computing system 1100 is merely illustrative and is not intended to limit the scope of the techniques described herein. Computing system 1100 may include any combination of devices or software that may perform or otherwise provide for the performance of the techniques described herein. For example, computing system 1100 may include or be a combination of a cloud-computing system, a data center, a server rack, a server, a virtual server, a desktop computer, a laptop computer, a tablet computer, a server device, a client device, a mobile telephone, a personal digital assistant (PDA), a mobile audio or video player, a game console, a vehicle-mounted computer, or a Global Positioning System (GPS), or the like. Computing system 1100 may also be connected to other devices that are not illustrated, or may operate as a stand-alone system. In addition, the functionality provided by the illustrated components may in some embodiments be combined in fewer components or distributed in additional components. Similarly, in some embodiments, the functionality of some of the illustrated components may not be provided or other additional functionality may be available.

Those skilled in the art will also appreciate that while various items are illustrated as being stored in memory or on storage while being used, these items or portions of them may be transferred between memory and other storage devices for purposes of memory management and data integrity. Alternatively, in other embodiments some or all of the software components may execute in memory on another device and communicate with the illustrated computer system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computing system 1100 may be transmitted to computing system 1100 via transmission media or signals such as electrical, electromagnetic, or digital signals, conveyed via a communication medium such as a network or a wireless link. Various embodiments may further include receiving, sending, or storing instructions or data implemented in accordance with the foregoing description upon a computer-accessible medium. Accordingly, the present techniques may be practiced with other computer system configurations.

While various items are illustrated as being stored in memory or on storage while being used, these items or portions of them may be transferred between memory and other storage devices for purposes of memory management and data integrity. Alternatively, in other embodiments some or all of the software components may execute in memory on another device and communicate with the illustrated computer system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computer system may be transmitted to computer system via transmission media or signals such as electrical, electromagnetic, or digital signals, conveyed via a communication medium such as a network or a wireless link. Various embodiments may further include receiving, sending, or storing instructions or data implemented in accordance with the foregoing description upon a computer-accessible medium. Accordingly, the present techniques may be practiced with other computer system configurations.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine readable medium. In some cases, notwithstanding use of the singular term “medium,” the instructions may be distributed on different storage devices associated with different computing devices, for instance, with each computing device having a different subset of the instructions, an implementation consistent with usage of the singular term “medium” herein. In some cases, third party content delivery networks may host some or all of the information conveyed over networks, in which case, to the extent information (e.g., content) is said to be supplied or otherwise provided, the information may be provided by sending instructions to retrieve that information from a content delivery network.

The reader should appreciate that the present application describes several independently useful techniques. Rather than separating those techniques into multiple isolated patent applications, applicants have grouped these techniques into a single document because their related subject matter lends itself to economies in the application process. But the distinct advantages and aspects of such techniques should not be conflated. In some cases, embodiments address all of the deficiencies noted herein, but it should be understood that the techniques are independently useful, and some embodiments address only a subset of such problems or offer other, unmentioned benefits that will be apparent to those of skill in the art of reviewing the present disclosure. Due to costs constraints, some techniques disclosed herein may not be presently claimed and may be claimed in later filings, such as continuation applications or by amending the present claims. Similarly, due to space constraints, neither the Abstract nor the Summary of the Invention sections of the present document should be taken as containing a comprehensive listing of all such techniques or all aspects of such techniques.

It should be understood that the description and the drawings are not intended to limit the present techniques to the particular form disclosed, but to the contrary, the intention is to cover all modifications, equivalents, and alternatives falling within the spirit and scope of the present techniques as defined by the appended claims. Further modifications and alternative embodiments of various aspects of the techniques will be apparent to those skilled in the art in view of this description. Accordingly, this description and the drawings are to be construed as illustrative only and are for the purpose of teaching those skilled in the art the general manner of carrying out the present techniques. It is to be understood that the forms of the present techniques shown and described herein are to be taken as examples of embodiments. Elements and materials may be substituted for those illustrated and described herein, parts and processes may be reversed or omitted, and certain features of the present techniques may be utilized independently, all as would be apparent to one skilled in the art after having the benefit of this description of the present techniques. Changes may be made in the elements described herein without departing from the spirit and scope of the present techniques as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Similarly, reference to “a computer system” performing step A and “the computer system” performing step B can include the same computing device within the computer system performing both steps or different computing devices within the computer system performing steps A and B. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. Limitations as to sequence of recited steps should not be read into the claims unless explicitly specified, e.g., with explicit language like “after performing X, performing Y,” in contrast to statements that might be improperly argued to imply sequence limitations, like “performing X on items, performing Y on the X'ed items,” used for purposes of making claims more readable rather than specifying sequence. Statements referring to “at least Z of A, B, and C,” and the like (e.g., “at least Z of A, B, or C”), refer to at least Z of the listed categories (A, B, and C) and do not require at least Z units in each category. Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device. Features described with reference to geometric constructs, like “parallel,” “perpendicular/orthogonal,” “square”, “cylindrical,” and the like, should be construed as encompassing items that substantially embody the properties of the geometric construct, e.g., reference to “parallel” surfaces encompasses substantially parallel surfaces. The permitted range of deviation from Platonic ideals of these geometric constructs is to be determined with reference to ranges in the specification, and where such ranges are not stated, with reference to industry norms in the field of use, and where such ranges are not defined, with reference to industry norms in the field of manufacturing of the designated feature, and where such ranges are not defined, features substantially embodying a geometric construct should be construed to include those features within 15% of the defining attributes of that geometric construct. The terms “first”, “second”, “third,” “given” and so on, if used in the claims, are used to distinguish or otherwise identify, and not to show a sequential or numerical limitation. As is the case in ordinary usage in the field, data structures and formats described with reference to uses salient to a human need not be presented in a human-intelligible format to constitute the described data structure or format, e.g., text need not be rendered or even encoded in Unicode or ASCII to constitute text; images, maps, and data-visualizations need not be displayed or decoded to constitute images, maps, and data-visualizations, respectively; speech, music, and other audio need not be emitted through a speaker or decoded to constitute speech, music, or other audio, respectively. Computer implemented instructions, commands, and the like are not limited to executable code and can be implemented in the form of data that causes functionality to be invoked, e.g., in the form of arguments of a function or API call. To the extent bespoke noun phrases (and other coined terms) are used in the claims and lack a self-evident construction, the definition of such phrases may be recited in the claim itself, in which case, the use of such bespoke noun phrases should not be taken as invitation to impart additional limitations by looking to the specification or extrinsic evidence.

In this patent, to the extent any U.S. patents, U.S. patent applications, or other materials (e.g., articles) have been incorporated by reference, the text of such materials is only incorporated by reference to the extent that no conflict exists between such material and the statements and drawings set forth herein. In the event of such conflict, the text of the present document governs, and terms in this document should not be given a narrower reading in virtue of the way in which those terms are used in other materials incorporated by reference.

Grouped, numerated embodiments are listed below by way of example. Reference to prior characterizations of embodiments within are within each group.

### Embodiments

1. An object motion sensitive circuit comprising: a photodetector, wherein the photodetector detects light intensity; and a thresholding circuit, wherein the thresholding circuit determines if a magnitude of a difference in the light intensity detected by the photodetector between a first occurrence and a second occurrence exceeds a threshold; and wherein the thresholding circuit outputs a signal corresponding to the determination to a processor or storage.
2. The circuit of embodiment 1, wherein the photodetector is a photodiode.
3. The circuit of embodiment 1, further comprising a sensor, wherein the sensor comprises the photodetector.
4. The circuit of embodiment 3, wherein the sensor is an active pixel sensor.
5. The circuit of embodiment 4, wherein the active pixel sensor is a three-transistor sensor.
6. The circuit of embodiment 4, further comprising a sampling circuit, wherein the sampling circuit determines the difference in the light intensity detected by the photodetector between a first time and a second time.
7. The circuit of embodiment 3, wherein the sensor is a dynamic vision sensor.
8. The circuit of embodiment 7, wherein the dynamic vision sensor comprises a logarithmic photoreceptor.
9. The circuit of embodiment 7, further comprising a difference amplifier, wherein the difference amplifier determines the difference in the light intensity detected by the photodetector between a first time and a second time.
10. The circuit of embodiment 1, further comprising a buffer, wherein the buffer isolates the photodetector from feedback of the thresholding circuit.
11. The circuit of embodiment 1, wherein the signal output by the circuit is a bipolar spike.
12. The circuit of embodiment 1, wherein the signal output by the circuit is determined at times controlled by a timing control signal.
13. The circuit of embodiment 1, wherein the signal output by the circuit is determined asynchronously.
14. The circuit of embodiment 1, further comprising signal conditioning circuitry.
15. The circuit of embodiment 1, further comprising 2T or 3T NVM circuity, wherein the thresholding circuit comprises 2T or 3T NVM circuitry or is in series with 2T or 3T NVM circuitry, and wherein the thresholding circuit determines if a magnitude of a difference in the light intensity detected by the photodetector between a first occurrence and a second occurrence exceeds a threshold based on the 2T or 3T NVM circuitry.
16. The circuit of embodiment 1, wherein the first occurrence is at a first time and wherein the second occurrence is at a second time, different from the first time.
17. The circuit of embodiment 1, wherein the photodetector and the thresholding circuit are homogeneously integrated.
18. The circuit of embodiment 1, wherein the photodetector and the thresholding circuit are heterogeneously integrated.
19. The circuit of any one of embodiments 1 to 18, wherein the circuit is distributed over multiple die.
20. The circuit of any one of embodiments 1 to 18, wherein the circuit comprises multiple dies integrated by three-dimensional integration.
21. A sensor array comprising:

multiple of any one of the circuits of embodiments 1 to 19.

22. The sensor array of embodiment 21, further comprising:

wherein a set of the photodetectors of the multiple circuits correspond to a center region and wherein a set of photodetectors of the multiple circuits correspond to a surround region;

a integration circuit,
wherein the integration circuit determines if a difference in outputs of the set of photodetectors corresponding to the center region and outputs of the set of photodetectors corresponding to the surround region; and
wherein the integration circuit outputs a signal corresponding to the determination to the processor or storage.
   23. The sensor array of embodiment 21, wherein the outputs of the circuits are applied to a capacitor.
   24. A receptive field sensor comprising multiple of any one of the sensor arrays of embodiments 21 to 23.
   25. The receptive field sensor of embodiment 24, wherein at least some of the set of the photodetectors corresponding to the surround region of a first sensor array lie within the set of the photodetectors corresponding to the center region of a second sensor array.
   26. A looming detection circuit comprising:

multiple photodetectors,
wherein some of the photodetectors are ON photodetectors that generate ON bipolar-spikes in response to an increase in light intensity greater than a first threshold, and
wherein some of the photodetectors are OFF photodetectors that generate OFF bipolar-spikes in response to a decrease in light intensity greater than a second threshold;

multiple transistors,
wherein the transistors are arranged in pairs, wherein each pair comprises an ON transistor connected to an ON photodetector and an OFF transistor connected to an OFF photodetector;

a capacitor,
wherein the capacitor is connected to outputs of the multiple transistors; and

a comparator circuit,
wherein the comparator circuit determines at least if a magnitude of a charge applied to the capacitor is greater than a threshold; and
wherein the comparator circuit outputs a signal corresponding to the determination to a processor or storage.
   27. The circuit of embodiment 26, wherein the comparator circuit further determines if a magnitude of a charge applied to the capacitor is within a range of a second threshold and wherein the comparator circuit outputs a second signal corresponding to the determination to a processor or storage.
   28. The circuit of embodiment 26, further comprising signal conditioning circuitry.
   29. The circuit of embodiment 26, wherein the comparator circuit comprises 2T or 3T NVM circuitry.
   30. The circuit of embodiment 26, further comprising 2T or 3T NVM circuitry, wherein the multiple transistors comprise 2T or 3T NVM circuitry or are in series with 2T or 3T NVM circuitry.
   31. The circuit of embodiment 27, wherein the threshold and the second threshold are substantially equal.
   32. The circuit of embodiment 27, wherein the second threshold is equal to half of a supply voltage.
   33. The circuit of embodiment 27 or 31, wherein the threshold is substantially equal to half of a supply voltage.
   34. The circuit of embodiment 26, wherein source of the ON transistor is coupled to an input voltage.
   34. The circuit of embodiment 26, wherein source of the OFF transistor is coupled to ground.
   36. The circuit of embodiment 26, where gate of the ON transistor is coupled to the ON photodetector.
   37. The circuit of embodiment 26, wherein gate of the OFF transistor is coupled to the OFF photodetector.
   38. The circuit of embodiment 26, wherein the circuit is homogeneously integrated.
   39. The circuit of embodiment 26, wherein at least one of the multiple photodetectors, multiple transistors, capacitor, and comparator circuit is heterogeneously integrated.
   40. The circuit of any one of embodiments 26 to 37, wherein the circuit is distributed over multiple die.
   41. The circuit of any one of embodiments 26 to 37, wherein the circuit comprises multiple dies integrated by three-dimensional integration.

1. An object motion sensitive circuit comprising:
a photodetector, wherein the photodetector detects light intensity; and
a thresholding circuit,
wherein the thresholding circuit determines if a magnitude of a difference in the light intensity detected by the photodetector between a first occurrence and a second occurrence exceeds a threshold; and
wherein the thresholding circuit outputs a signal corresponding to the determination to a processor or storage.

2. The circuit of claim 1, wherein the photodetector is a photodiode.

3. The circuit of claim 1, further comprising a sensor, wherein the sensor comprises the photodetector.

4. The circuit of claim 3, wherein the sensor is an active pixel sensor.

5. The circuit of claim 4, wherein the active pixel sensor is a three-transistor sensor.

6. The circuit of claim 4, further comprising a sampling circuit, wherein the sampling circuit determines the difference in the light intensity detected by the photodetector between a first time and a second time.

7. The circuit of claim 3, wherein the sensor is a dynamic vision sensor.

8. The circuit of claim 7, wherein the dynamic vision sensor comprises a logarithmic photoreceptor.

9. The circuit of claim 7, further comprising a difference amplifier, wherein the difference amplifier determines the difference in the light intensity detected by the photodetector between a first time and a second time.

10. The circuit of claim 1, further comprising a buffer, wherein the buffer isolates the photodetector from feedback of the thresholding circuit.

11. The circuit of claim 1, wherein the signal output by the circuit is a bipolar spike.

12. The circuit of claim 1, wherein the signal output by the circuit is determined at times controlled by a timing control signal.

13. The circuit of claim 1, wherein the signal output by the circuit is determined asynchronously.

14. The circuit of claim 1, further comprising signal conditioning circuitry.

15. The circuit of claim 1, further comprising two terminal (2T) or three terminal (3T) non-volatile memory (NVM) circuity, wherein the thresholding circuit comprises 2T or 3T NVM circuitry or is in series with 2T or 3T NVM circuitry, and wherein the thresholding circuit determines if a magnitude of a difference in the light intensity detected by the photodetector between a first occurrence and a second occurrence exceeds a threshold based on the 2T or 3T NVM circuitry.

16. The circuit of claim 1, wherein the first occurrence is at a first time and wherein the second occurrence is at a second time, different from the first time.

17. The circuit of claim 1, wherein the photodetector and the thresholding circuit are homogeneously integrated.

18. The circuit of claim 1, wherein the photodetector and the thresholding circuit are heterogeneously integrated.

19. The circuit of claim 1, wherein the circuit is distributed over multiple die.

20. The circuit of claim 1, wherein the circuit comprises multiple dies integrated by three-dimensional integration.

21.-41. (canceled)
